(19) United States
(12) Patent Application Publication
(10) Pub. No.: US 2008/0305627 A1
(43) Pub. Date: Dec. 11, 2008

(54) METHOD OF FORMING A CONTACT PLUG AND METHOD OF FORMING A SEMICONDUCTOR DEVICE

(75) Inventor: Atsushi MAEKAWA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC, Tokyo (JP)

(21) Appl. No.: 12/133,508

(22) Filed: Jun. 5, 2008

(30) Foreign Application Priority Data
Jun. 8, 2007 (JP) 2007-153262

(51) Int. Cl. H01L 21/4763

(52) U.S. Cl. 438/637; 257/E21.577

(57) ABSTRACT

A method of forming a contact plug includes the following processes. A dummy film is formed over a substrate. The dummy film may include amorphous carbon as a main material. At least one contact hole is formed in the dummy film. At least one contact plug is formed in the at least one contact hole.

### BACKGROUND OF THE INVENTION

1. Field of the Invention

The present invention generally relates to a method of forming a contact plug and a method of forming a semiconductor device. More specifically, the present invention relates to a method of forming a contact plug in an insulating film by using a self-aligned contact.

Priority is claimed on Japanese Patent Application No. 2007-153262, filed Jun. 8, 2007, the content of which is incorporated herein by reference.

2. Description of the Related Art

All patents, patent applications, patent publications, scientific articles, and the like, which will hereinafter be cited or identified in the present application, will hereby be incorporated by reference in their entirety in order to describe more fully the state of the art to which the present invention pertains.

In recent years, memory cells have been on the further shrinkage as the requirements for the memory capacity and the high speed performance of DRAM (Dynamic Random Access Memory) have been on the increases. In order to shrink DRAM memory cells, it is necessary to shrink a MOS transistor and a capacitor which are formed over a semiconductor substrate as well as shrink interconnections and contact holes which provide electrical connections between them. Interconnections and contact plugs must be formed so as to be electrically isolated from each other. Further shrinkage of the memory cell makes it difficult to form the interconnections and the contact plugs that are electrically separated.

FIG. 20 is a fragmentary cross sectional elevation view illustrating a conventional DRAM memory cell, taken along a line that runs parallel to a bit line and perpendicular to a word line.

A semiconductor substrate 101 has device isolation regions 102, and n-diffusion layers 103. A gate insulating film 104 is formed on the surface of the semiconductor substrate 101. First interconnections are formed on the gate insulating film 104. The first interconnections perform as gate electrodes that are not illustrated and as word lines 105. The gate electrode, the n-diffusion layers 103 and the gate insulating film 104 constitute a MOS transistor. The word lines 105 have patterns which are aligned at a constant pitch. A first inter-layer insulator 106 covers the word lines 105. First contact plugs 107 and 108 are formed, which penetrate the first inter-layer insulator 106. The first contact plugs 107 and 108 are each separated by the first inter-layer insulator 106 from the word lines 105. The first contact plugs 107 and 108 are each interposed between adjacent two of the word lines 105.

A second inter-layer insulator 109 is formed on the surfaces of the first contact plugs 107 and 108 and the first inter-layer insulator 106. Second contact plugs 110 as bit contact plugs are formed which penetrate the second inter-layer insulator 109. The second contact plugs 110 are connected with the first contact plugs 107. Second interconnections performing as bit lines 111 are formed over the second inter-layer insulator 109, wherein the second interconnections as the bit lines 111 are connected with the second contact plugs 110. A third inter-layer insulator 112 covers the bit lines 111. Third contact plugs 113 as capacitor contact plugs are formed, which penetrate the third inter-layer insulator 112, the bit lines 111 and the second inter-layer insulator 109. The third contact plugs 113 reach the first contact plugs 108 so that the third contact plugs 113 are connected to the first contact plugs 108.

A fourth inter-layer insulator 114 is formed on the surfaces of the third contact plugs 113 and the third inter-layer insulator 112. A cylinder hole 120 is formed in the fourth inter-layer insulator 114. The cylinder hole 120 penetrates the fourth inter-layer insulator 114. The cylinder hole 120 reaches the third contact plugs 113 and those peripheral portions of the surface of the third inter-layer insulator 112. A bottom electrode 115 of a capacitor is formed on the side walls and the bottom of the cylinder hole 120. The bottom electrode 115 is connected with the third contact plugs 113. A capacitive insulating film 116 is formed on the bottom electrode 115 in the cylinder hale 120 as well as formed on the surface of the fourth inter-layer insulator 114. A top electrode 117 is formed on the capacitive insulating film 116. The top electrode 117 is present in the cylinder hole 120 and over the fourth inter-layer insulator 114. A fifth inter-layer insulator 118 is formed over the top electrode 117. Third interconnections 119 are formed over the fifth inter-layer insulator 118.

The requirements for further shrinkage of the memory cells in DRAM have been on the increase as further increasing the density of integrations of the DRAM has been required. Plain area allocated for each element is reduced. It is no longer impossible to obtain a sufficient margin for process for forming each contact plug. When a cell contact plug such as the first contact plug 107 or 108 is interposed between the adjacent two of the word lines 105, it is effective for ensuring the process margin to increase the thickness of the inter-layer insulator which separates the word lines 105 from the cell contact plugs. Increasing the thickness of the inter-layer insulator which separates the word lines 105 from the cell contact plugs makes small the process margin of the contact plugs, thereby making it more difficult to form the contact plug in a limited small area. In order to reduce the hardship to form the contact plugs, a self-aligned contact method is available.

FIGS. 21 through 25 are fragmentary cross sectional elevation views illustrating semiconductor devices in sequential steps involved in a conventional method of forming the cell contact plugs using the self-aligned contact technique.

As shown in FIG. 21, word lines 105 are formed over a semiconductor substrate 101 by using silicon nitride films as masks. Silicon nitride side walls 121 are formed on side walls of the stacks of the word lines 105 and the silicon nitride films 120 by a known method.

As shown in FIG. 22, a first inter-layer insulator 106 is formed over the semiconductor substrate 101 so that the first inter-layer insulator 106 covers the silicon nitride films 120 and the silicon nitride side walls 121. The first inter-layer insulator 106 may be made of silicon oxide. The first inter-layer insulator 106 may have a thickness of 600 nanometers. The first inter-layer insulator 106 is then planarized by a CMP (chemical mechanical polishing) method so that the thickness of the first inter-layer insulator 106 is reduced to 400 nanometers. A photo-resist 122 is formed over the first inter-layer insulator 106. The photo-resist 122 is patterned to form openings 122a therein so that the openings 122a are present in the contact hole formation regions. In order to clarify the problem with the prior art, it is considered as an example that the width of the opening 122a of the photo-resist is wider than the distance between the word lines 105 so that the opening 122a partially overlaps the word lines 105.

As shown in FIG. 23, the photo-resist 122 is used as a mask to selectively etch the first inter-layer insulator 106, thereby forming first contact holes 123. For the etching process, the silicon nitride film 120 and the side walls 121 which cover the word line 105 have lower etching rate than that of silicon oxide. Even if the etching region namely the opening 122a of the photo-resist 122 overlaps the word line 105, then once the silicon nitride film 120 and the side walls 121 are exposed, the first contact holes 123 are self-aligned to the silicon nitride film 120 and the side walls 121, while the word line 105 remains unexposed. Even if the opening 122a of the photo-resist 112 is excessively widen, the first contact hole 123 can be formed while the word line 105 remains unexposed.

As shown in FIG. 24, a phosphorus-doped polycrystalline silicon film 124 is formed so as to fill up the contact holes 123.

As shown in FIG. 25, an unnecessary portion of the phosphorus-doped polycrystalline silicon film 124 is removed by the CMP method, wherein the unnecessary portion is present over the first inter-layer insulator 106. As a result, the first contact plugs 107, 108 made of polycrystalline silicon are formed.

Further shrinking requirements would have made it difficult to form highly reliable contact holes even the self-aligned contact method is used. In accordance with the self-aligned contact method, the silicon nitride film having lower etching rate than that of the silicon oxide film covers the word line so as to prevent the word line from being exposed during the process for etching the silicon oxide film. The dry etching rate ratio of silicon oxide to silicon nitride is about 5. This dry etching rate is difficult to be significantly changed by changing the dry etching conditions because both silicon oxide and silicon nitride are silicon compounds and it is difficult to increase the difference in dry etching rate between silicon oxide and silicon nitride.

When the contact holes are formed under the conditions described above, the silicon nitride film resides over the word line as shown in the circular mark “A” in FIG. 23. The thickness of the residual portion of the silicon nitride film will be considered.

The first inter-layer insulator 106 of silicon oxide is etched by using the photo-resist 122 with the opening 122a as a mask. Limited portions of the first inter-layer insulator 106 are positioned under the openings 122a of the photo-resist 122. Before the silicon nitride film 120 and the side walls 121 are exposed, the limited portions of the first inter-layer insulator 106 are etched at almost uniform etching rate. Once the silicon nitride film 120 and the side walls 121 have been exposed, the first inter-layer insulator 106 is continuously etched at the same etching rate, while the silicon nitride film 120 and the side walls 121 are etched at a lower etching rate than the etching rate of the first inter-layer insulator 106.

The thickness of the etching-portion of the silicon oxide film, which needs to be etched after the silicon nitride film 120 and the side walls 121 are exposed, is 240 nanometers which is equal to the sum of the thickness of 100 nanometers of the silicon nitride film 120 and the thickness of 140 nanometers of the word line 104. Under the condition that the etching rate ratio of silicon oxide to silicon nitride is 5, the silicon oxide film is etched by 240 nanometers, while the silicon nitride film is etched by about 50 nanometers. The thickness of the silicon nitride film 120 over the word lines 105 is about 100 nanometers. Thus, the residual portion of the silicon nitride film 120 has a thickness of 50 nanometers. As shown in the circular mark “A” in FIG. 25, the residual silicon nitride film 120 having the thickness of 50 nanometers can prevent short circuit between the first contact plugs 107, 108 and the word line 105.

Reducing the diameter of the contact holes due to shrinkage of the memory cell signifies that the etching rate is reduced as the depth of the contact hole is increased, thereby making it difficult to maintain the above-described etching rate ratio.

By the etching process shown in FIG. 23, the first contact hole 123 is formed in the first inter-layer insulator 106. The etching rate of the silicon oxide film is reduced as the depth becomes deeper, resulting in that the etching rate ratio of the silicon oxide film to the silicon nitride film is reduced to about 3. As a result, the silicon nitride film 120 having a thickness of 100 nanometers over the word line 105 has already been etched entirely before the n-diffusion layer 103 is exposed. Thus, a short circuit is formed between the first contact plugs 107, 108 and the word line 108 at the position marked by the circular mark “A” in FIG. 25. Increasing the thicknesses of the silicon nitride film 120 and the side walls 121 may solve this problem, while making it difficult to form the first inter-layer insulator 106.

In view of the above, it will be apparent to those skilled in the art from this disclosure that there exists a need for an improved method of forming a contact plug and an improved method of forming the semiconductor device. This invention addresses this need in the art as well as other needs, which will become apparent to those skilled in the art from this disclosure.

### SUMMARY OF THE INVENTION

Accordingly, it is a primary object of the present invention to provide a method of forming a contact plug.

It is another object of the present invention to provide a method of forming a contact plug free from the above-described issues.

It is a further object of the present invention to provide a method of forming a contact plug in an inter-layer insulator by a self-aligned contact method, which can prevent that a word line is exposed by etching an insulator covering the word line.

It is a still further object of the present invention to provide a method of forming a contact plug by a self-aligned contact method, which can prevent that a short circuit is formed between a contact plug and a word line.

It is yet a further object of the present invention to provide a method of forming a contact plug that is highly reliable.

It is an additional object of the present invention to provide a method of forming a semiconductor device using a method of forming a contact plug.

It is another object of the present invention to provide a method of forming a semiconductor device using a method of forming a contact plug free from the above-described issues.

It is still another object of the present invention to provide a method of forming a semiconductor device using a method of forming a contact plug in an inter-layer insulator by a self-aligned contact method, which can prevent that a word line is exposed by etching an insulator covering the word line.

It is yet another object of the present invention to provide a method of forming a semiconductor device using a method of forming a contact plug by a self-aligned contact method, which can prevent that a short circuit is formed between a contact plug and a word line.

It is further more object of the present invention to provide a method of forming a semiconductor device using a method of forming a contact plug that is highly reliable.

In accordance with a first aspect of the present invention, a method of forming a contact plug may include, but is not limited to, the following processes. A dummy film is formed over a substrate. The dummy film may include amorphous carbon as a main material. At least one contact hole is formed in the dummy film. At least one contact plug is formed in the at least one contact hole.

When interconnection layers covered with insulating films are formed over the substrate, the contact hole can be formed while the interconnection layers remain covered with the insulating films. The insulating films prevent short circuit between the contact plug and the interconnection layers.

In some cases, the method of forming the contact plug may further include the following processes. Interconnection layers may be formed over the substrate. A first insulating film may be formed over the substrate. The first insulating film covers the interconnection layers. Forming the dummy film over the substrate may be forming the dummy film which covers the first insulating film. Forming the at least one contact hole in the dummy film may be carrying out an etching process under condition that an etching rate of the dummy film is higher than an etching rate of the first insulating film so that the at least one contact hole penetrates the dummy film and the surface of the substrate is exposed.

The contact hole can be formed while the interconnection layers remain covered with the insulating films. The insulating films prevent short circuit between the contact plug and the interconnection layers.

In some cases, the method may further include the following processes. The dummy film may be removed by a dry etching process using a reaction gas that is substantially free of halogen, after the at least one contact plug is formed.

The dummy film can be removed without providing any substantive influence to the other elements or structures.

In some cases, forming the at least one contact hole may be realized by carrying out a dry etching process using a reaction gas that is substantially free of halogen. The etching rate ratio of the dummy film to the first insulating film is extremely large. The dummy film can be etched while the first insulating film resides covering the interconnection layer. The first insulating film prevents the interconnection layer from being exposed. The first insulating film prevents the short circuit between the contact plug and the interconnection layer.

In some cases, the reaction gas may contain at least one of oxygen, hydrogen, and ammonium. The etching rate ratio of the dummy film to the first insulating film is extremely large. The dummy film can be etched while the first insulating film resides covering the interconnection layer. The first insulating film prevents the interconnection layer from being exposed. The first insulating film prevents the short circuit between the contact plug and the interconnection layer.

In some cases, a ratio in etching rate of the dummy film to the first insulating film may be at least 100. The dummy film can be etched while the first insulating film resides covering the interconnection layer. The first insulating film prevents the interconnection layer from being exposed. The first insulating film prevents the short circuit between the contact plug and the interconnection layer.

In some cases, the method may further include the following processes. A second insulating film is formed on side walls of the at least one contact hole. The at least one contact plug is formed adjacent to the second insulating film.

Even if voids are formed in the dummy film of amorphous carbon, the second insulating film plugs voids that are adjacent to the contact hole, thereby preventing that the conductive material of the contact plug enters into the voids and that the short circuit is formed between the contact plugs.

In some cases, the etching process is carried out under condition that the etching rate of the dummy film is higher than an etching rate of the second insulating film to prevent the second insulating film from being etched. The second insulating film plugs voids that are adjacent to the contact hole, thereby preventing that the conductive material of the contact plug enters into the voids and that the short circuit is formed between the contact plugs.

In accordance with a second aspect of the present invention, a method of forming a semiconductor device may include the following processes. A dummy film is formed over a substrate having interconnection layers. The dummy film covers the interconnection layers. The dummy film includes amorphous carbon as a main material. At least one contact hole is formed in the dummy film. At least one contact plug is formed in the at least one contact hole.

When interconnection layers covered with insulating films are formed over the substrate, the contact hole can be formed while the interconnection layers remain covered with the insulating films. The insulating films prevent short circuit between the contact plug and the interconnection layers.

In some cases, the method may further include forming a first insulating film over the substrate. The first insulating film covers the interconnection layers. Forming the dummy film over the substrate may be forming the dummy film which covers the first insulating film. Forming the at least one contact hole in the dummy film may be carrying out an etching process under condition that an etching rate of the dummy film is higher than an etching rate of the first insulating film so that the at least one contact hole penetrates the dummy film and the surface of the substrate is exposed.

The contact hole can be formed while the interconnection layers remain covered with the insulating films. The insulating films prevent short circuit between the contact plug and the interconnection layers. This can improve the yield of the semiconductor device that is reliable.

In some cases, the method may further include the following processes. The dummy film may be removed by a dry etching process using a reaction gas that is substantially free of halogen, after the at least one contact plug is formed. An inter-layer insulator may be formed over the substrate. The inter-layer insulator covers the at least one contact plug and the first insulating film. The dummy film can be removed without providing any substantive influence to the other elements or structures.

In some cases, the interconnection layers may have stripe patterns. The at least one contact hole may be positioned between the interconnection layers. The above-described advantages are significant in such case.

In some cases, the first insulating film may include mainly at least any one of silicon oxide and silicon nitride, whereby the etching rate ratio of the dummy film to the first insulating film is extremely large. The dummy film can be etched while the first insulating film resides covering the interconnection layer. The first insulating film prevents the interconnection layer from being exposed. The first insulating film prevents the short circuit between the contact plug and the interconnection layer.

In some cases, the first insulating film may include mainly silicon oxide. Silicon oxide is relatively low in dielectric constant which may reduce an electric capacitance between the contact plug and the interconnection layer.

In some cases, forming the at least one contact hole may be realized by carrying out a dry etching process using a reaction gas that is substantially free of halogen. The etching rate ratio of the dummy film to the first insulating film is extremely large. The dummy film can be etched while the first insulating film resides covering the interconnection layer. The first insulating film prevents the interconnection layer from being exposed. The first insulating film prevents the short circuit between the contact plug and the interconnection layer.

In some cases, the reaction gas may contain at least one of oxygen, hydrogen, and ammonium. The etching rate ratio of the dummy film to the first insulating film is extremely large. The dummy film can be etched while the first insulating film resides covering the interconnection layer. The first insulating film prevents the interconnection layer from being exposed. The first insulating film prevents the short circuit between the contact plug and the interconnection layer.

In some cases, a ratio in etching rate of the dummy film to the first insulating film may be at least 100. The dummy film can be etched while the first insulating film resides covering the interconnection layer. The first insulating film prevents the interconnection layer from being exposed. The first insulating film prevents the short circuit between the contact plug and the interconnection layer.

In some cases, the method may further include the following processes. A second insulating film is formed on side walls of the at least one contact hole. The at least one contact plug is formed adjacent to the second insulating film.

Even if voids are formed in the dummy film of amorphous carbon, the second insulating film plugs voids that are adjacent to the contact hole, thereby preventing that the conductive material of the contact plug enters into the voids and that the short circuit is formed between the contact plugs.

In some cases, the etching process is carried out under condition that the etching rate of the dummy film is higher than an etching rate of the second insulating film to prevent the second insulating film from being etched. The second insulating film plugs voids that are adjacent to the contact hole, thereby preventing that the conductive material of the contact plug enters into the voids and that the short circuit is formed between the contact plugs.

The dummy film of amorphous carbon is etched, while the interconnection layer is covered by the insulating film such as the silicon oxide film or the silicon nitride film. The dummy film of amorphous carbon can be etched by a dry etching process using a halogen-free reaction gas in plasma state, for example, a halogen-free reaction gas that contains oxygen, hydrogen or ammonium. The contact hole can be formed in the dummy film of amorphous carbon while the insulating film covering the interconnection layer is not etched substantially. The insulating film covering the interconnection layer prevents short circuit between the contact plug and the interconnection layer.

The dummy film may be removed by a dry etching process using a reaction gas that is substantially free of halogen, after the at least one contact plug is formed. The dummy film can be removed without providing any substantive influence to the other elements or structures. After the contact plug is formed, the same or similar processes as those of the prior art can be usable to complete the semiconductor device.

The silicon oxide film can be used for covering the interconnection layer. The silicon oxide film is lower in dielectric contact than the silicon nitride film that has been used in the prior art such as the self-aligned contact technique. The insulating film having lower dielectric constant reduces the electric capacitance between the contact plug and the interconnection layer.

These and other objects, features, aspects, and advantages of the present invention will become apparent to those skilled in the art from the following detailed descriptions taken in conjunction with the accompanying drawings, illustrating the embodiments of the present invention.

### BRIEF DESCRIPTION OF THE DRAWINGS

Referring now to the attached drawings which form a part of this original disclosure:

FIG. 1 is a fragmentary cross sectional elevation view illustrating a memory cell structure of a semiconductor device, taken along a line that runs parallel to a bit line and perpendicular to a word line, which is formed by a method of forming it accordance with a first preferred embodiment of the present invention;

FIG. 2 is a fragmentary cross sectional elevation view illustrating a semiconductor device in a step involved in a method of forming the semiconductor device in accordance with the first embodiment of the present invention;

FIG. 3 is a fragmentary cross sectional elevation view illustrating a semiconductor device in a step, subsequent to the step of FIG. 2, involved in a method of forming the semiconductor device in accordance with the first embodiment of the present invention;

FIG. 4 is a fragmentary cross sectional elevation view illustrating a semiconductor device in a step, subsequent to the step of FIG. 3, involved in a method of forming the semiconductor device in accordance with the first embodiment of the present invention;

FIG. 5 is a fragmentary cross sectional elevation view illustrating a semiconductor device in a step, subsequent to the step of FIG. 4, involved in a method of forming the semiconductor device in accordance with the first embodiment of the present invention;

FIG. 6 is a fragmentary cross sectional elevation view illustrating a semiconductor device in a step, subsequent to the step of FIG. 5, involved in a method of forming the semiconductor device in accordance with the first embodiment of the present invention;

FIG. 7 is a fragmentary cross sectional elevation view illustrating a semiconductor device in a step, subsequent to the step of FIG. 6, involved in a method of forming the semiconductor device in accordance with the first embodiment of the present invention;

FIG. 8 is a fragmentary cross sectional elevation view illustrating a semiconductor device in a step, subsequent to the step of FIG. 7, involved in a method of forming the semiconductor device in accordance with the first embodiment of the present invention;

FIG. 9 is a fragmentary cross sectional elevation view illustrating a semiconductor device in a step, subsequent to the step of FIG. 8, involved in a method of forming the semiconductor device in accordance with the first embodiment of the present invention;

FIG. 10 is a fragmentary cross sectional elevation view illustrating a semiconductor device in a step, subsequent to the step of FIG. 9, involved in a method of forming the semiconductor device in accordance with the first embodiment of the present invention;

FIG. 11 is a fragmentary cross sectional elevation view illustrating a semiconductor device in a step, subsequent to the step of FIG. 10, involved in a method of forming the semiconductor device in accordance with the first embodiment of the present invention;

FIG. 12 is a fragmentary cross sectional elevation view illustrating a semiconductor device in a step, subsequent to the step of FIG. 11, involved in a method of forming the semiconductor device in accordance with the first embodiment of the present invention;

FIG. 13 is a fragmentary cross sectional elevation view illustrating a memory cell structure of a semiconductor device, taken along a line that runs parallel to a bit line and perpendicular to a word line, which is formed by a method of forming it accordance with a second preferred embodiment of the present invention;

FIG. 14 is a fragmentary cross sectional elevation view illustrating a semiconductor device in a step involved in a method of forming the semiconductor device in accordance with the second embodiment of the present invention;

FIG. 15 is a fragmentary cross sectional elevation view illustrating a semiconductor device in a step, subsequent to the step of FIG. 14, involved in a method of forming the semiconductor device in accordance with the first embodiment of the present invention;

FIG. 16 is a fragmentary cross sectional elevation view illustrating a semiconductor device in a step, subsequent to the step of FIG. 15, involved in a method of forming the semiconductor device in accordance with the first embodiment of the present invention;

FIG. 17 is a fragmentary cross sectional elevation view illustrating a semiconductor device in a step, subsequent to the step of FIG. 16, involved in a method of forming the semiconductor device in accordance with the first embodiment of the present invention;

FIG. 18 is a fragmentary cross sectional elevation view illustrating a semiconductor device in a step, subsequent to the step of FIG. 17, involved in a method of forming the semiconductor device in accordance with the first embodiment of the present invention;

FIG. 19 is a fragmentary cross sectional elevation view illustrating a semiconductor device in a step, subsequent to the step of FIG. 18, involved in a method of forming the semiconductor device in accordance with the first embodiment of the present invention;

FIG. 20 is a fragmentary cross sectional elevation view illustrating a conventional DRAM memory cell, taken along a line that runs parallel to a bit line and perpendicular to a word line;

FIG. 21 is a fragmentary cross sectional elevation view illustrating a semiconductor device in a step involved in a conventional method of forming the cell contact plugs using the self-aligned contact technique;

FIG. 22 is a fragmentary cross sectional elevation view illustrating a semiconductor device in a step sequential to the step of FIG. 21, involved in a conventional method of forming the cell contact plugs using the self-aligned contact technique;

FIG. 23 is a fragmentary cross sectional elevation view illustrating a semiconductor device in a step sequential to the step of FIG. 22, involved in a conventional method of forming the cell contact plugs using the self-aligned contact technique;

FIG. 24 is a fragmentary cross sectional elevation view illustrating a semiconductor device in a step sequential to the step of FIG. 23, involved in a conventional method of forming the cell contact plugs using the self-aligned contact technique; and

FIG. 25 is a fragmentary cross sectional elevation view illustrating a semiconductor device in a step sequential to the step of FIG. 24, involved in a conventional method of forming the cell contact plugs using the self-aligned contact technique.

### DETAILED DESCRIPTION OF THE INVENTION

Selected embodiments of the present invention will now be described with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

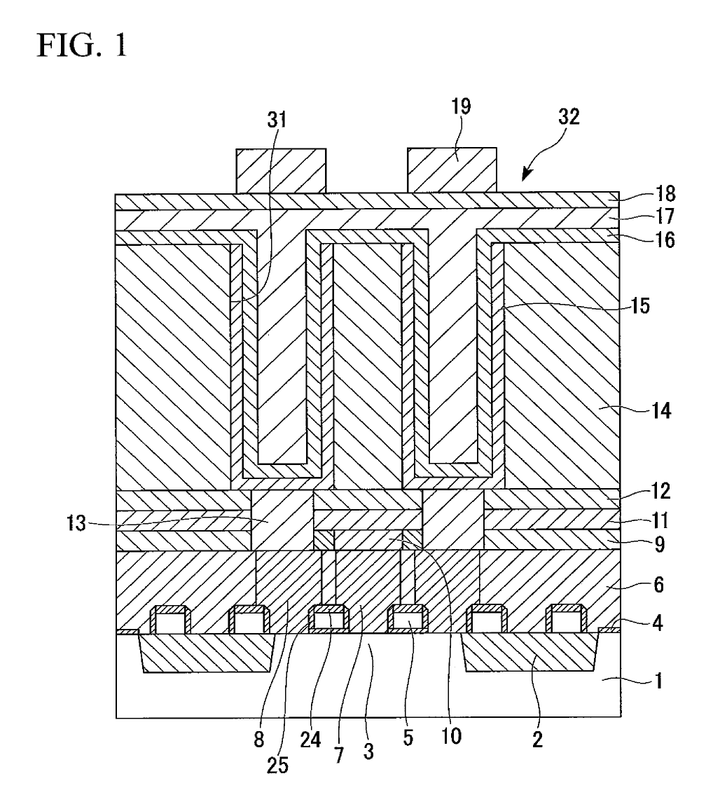

A first embodiment of the present invention will be described. An example of a semiconductor device that is formed by a method of forming it will be described. FIG. 1 is a fragmentary cross sectional elevation view illustrating a memory cell structure of a semiconductor device, taken along a line that runs parallel to a bit line and perpendicular to a word line, which is formed by a method of forming it accordance with a first preferred embodiment of the present invention.

A semiconductor device includes memory cells. The semiconductor device is formed on a semiconductor substrate 1. The memory cell includes a switching transistor that is not illustrated and a capacitor 32. The switching transistor is formed over the semiconductor substrate 1. The capacitor 32 is formed over inter-layer insulators 6, 9, and 12 over the semiconductor substrate 1.

The semiconductor substrate 1 has device isolation regions 2 and n-diffusion layers 3. The n-diffusion layers 3 perform as source and drain regions of a MOS transistor.

A gate insulating film 4 is provided over the surface of the semiconductor substrate 1. The gate insulating film 4 is formed by a thermal oxidation process. Gate electrodes that are not illustrated are formed on the gate insulating film 4. Word lines 5 of first interconnection layers having predetermined patterns are also formed on the gate insulating film 4. The word lines 5 have patterns which are aligned at a constant pitch. The word lines 5 are connected to the gate electrodes of the MOS transistors. In some cases, the word lines 5 are made of polycrystalline silicon. Silicon oxide films 24 are provided over the gate electrodes and the word lines 5. Side walls 25 are provided on side walls of the gate electrodes and the word lines 5. Other insulating films such as silicon nitride films may be used instead of the silicon oxide films 24 and the side walls 25.

A first inter-layer insulator 6 is formed over the gate insulating film 4. The first inter-layer insulator 6 covers the gate electrodes and the word lines 5. The first inter-layer insulator 6 is made of silicon oxide. First contact plugs 7 and 8 are formed which penetrate the first inter-layer insulator 6. The first contact plugs 7 and 8 perform as cell contact plugs. The first contact plugs 7 and 8 may be made of impurity doped polycrystalline silicon. The first contact plugs 7 and 8 are each disposed between adjacent two of the word lines 5.

A second inter-layer insulator 9 is provided over the first inter-layer insulator 6 and the first contact plugs 7. The second inter-layer insulator 9 may be made of silicon oxide. A second contact plug 10 is provided, which penetrates the second inter-layer insulator 9. The second contact plug 10 performs as a bit contact plug. The second contact plug 10 is made of a conductive material. The second contact plug 10 is connected to the first contact plug 7.

Bit lines 11 of second interconnection layers are formed over the second inter-layer insulator 9 and the second contact plug 10. The bit lines 11 have a predetermined pattern. The bit lines 11 may be made of a conductive material such as tungsten. The bit lines 11 are aligned at a contact pitch. The bit lines 11 run crossing over the word lines 5. The bit lines 11 are connected through the second contact plugs 10 and the first contact plugs 7 to the n-diffusion layers 3 that perform as the drain regions.

A third inter-layer insulator 12 is provided over the second inter-layer insulator 9 so that the third inter-layer insulator 12 covers the bit lines 11. The third inter-layer insulator 12 may be made of silicon oxide. Third contact plugs 13 are provided, which penetrate the third inter-layer insulator 12, the bit lines 11, the second inter-layer insulator 12. The third contact plugs 13 are made of impurity doped polycrystalline silicon. The third contact plugs 13 are connected to the first contact plugs 8.

A fourth inter-layer insulator 14 is provided over the third inter-layer insulator 12 and the third contact plugs 13. The fourth inter-layer insulator 14 may be made of silicon oxide. A cylinder hole 31 is formed, which penetrates the fourth inter-layer insulator 14. The cylinder hole 31 reaches the third contact plugs 13. A bottom electrode 15 is formed on side walls and bottom of the cylinder hole 31. The bottom electrode 15 is made of a conductive material. The bottom electrode 15 is connected to the third contact plugs 13. The bottom electrode 15 is connected through the third contact plug 13 and the first contact plug 8 to the n-diffusion layer 3 that performs as the source region.

A capacitive insulating film 16 having a high dielectric is provided on the bottom electrode 15 and on the surface of the fourth inter-layer insulator 15 which perform as separation walls for the cylinder hole 31. A top electrode 17 is provided on the capacitive insulating film 16. The top electrode 17 fills up the cylinder hole 31 and extends over the fourth inter-layer insulator 14. The top electrode 17 is made of a conductive material. The bottom electrode 15, the capacitive insulating film 16 and the top electrode 17 constitute a capacitor 32. A fifth inter-layer insulator 18 is provided over the top electrode 17. The fifth inter-layer insulator 18 may be made of silicon oxide film. Third interconnection layers 19 having a predetermined pattern are provided over the fifth inter-layer insulator 18.

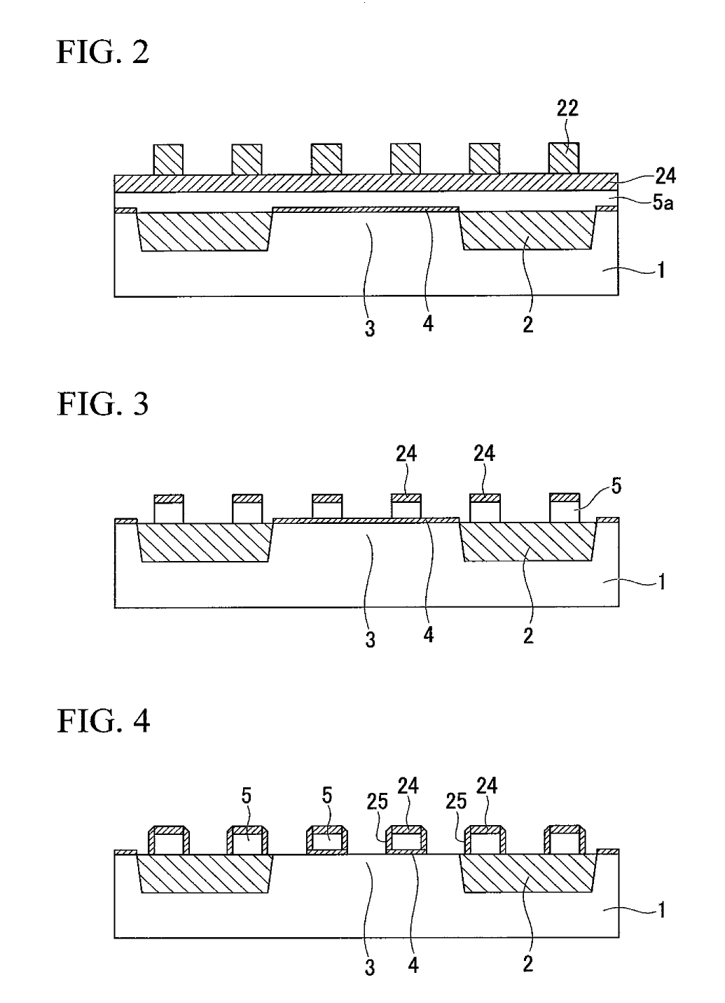

A method of forming a semiconductor device having contact plugs will be described. FIGS. 2 through 12 are fragmentary cross sectional elevation views illustrating semiconductor devices in sequential steps involved in a method of forming the same in accordance with the first embodiment of the present invention.

As shown in FIG. 2, device isolation regions 2 having a depth of 250 nanometers are selectively formed in a semiconductor substrate 1, thereby defining n-diffusion layers 3. A gate insulating film 4 is formed on the surface of the semiconductor substrate 1 by a thermal oxidation process.

A polycrystalline silicon film 5a having a thickness of 140 nanometers is formed over the gate insulating film 4. The polycrystalline silicon film 5a will be formed into word lines 5 in later process. A silicon oxide film 24 is formed on the polycrystalline silicon film 5a. The silicon oxide film 24 is formed by a CVD (chemical vapor deposition) method. The silicon oxide film 24 has a thickness of 100 nanometers. The silicon oxide film 24 will be used as a dry etching mask in a later dry etching process. A photo-resist pattern 22 which defines a pattern of word lines 5 is formed on the silicon oxide film 24.

As shown in FIG. 3, the photo-resist pattern 22 is used as a mask to carry out a dry etching process for selectively etching the silicon oxide film 24. The dry etching process is carried out using fluorine-containing reaction gas in plasma state. The silicon oxide film 24 is used as a mask to carry out another dry etching process for selectively etching the polycrystalline silicon film 5a. The dry etching process is carried out using chlorine-containing reaction gas in plasma state. At this step, the remaining silicon oxide film 24 has a reduced thickness of 30 nanometers over the word lines 5.

As shown in FIG. 4, side wall insulators 25 are formed by a known method on the side walls of the stacks of the word lines 5 and the silicon oxide films 24. The side wall insulators 25 may be made of silicon oxide. The side wall insulators 25 are formed by a CVD method. The side wall insulators 25 have a thickness of 20 nanometers. At this step, the tops of the word lines 5 are covered by the silicon oxide films 24 and the side walls of the word lines 5 are covered by the side wall insulators 25. In other cases, the silicon oxide films 24 and the side wall insulators 25 may be replaced by silicon nitride films.

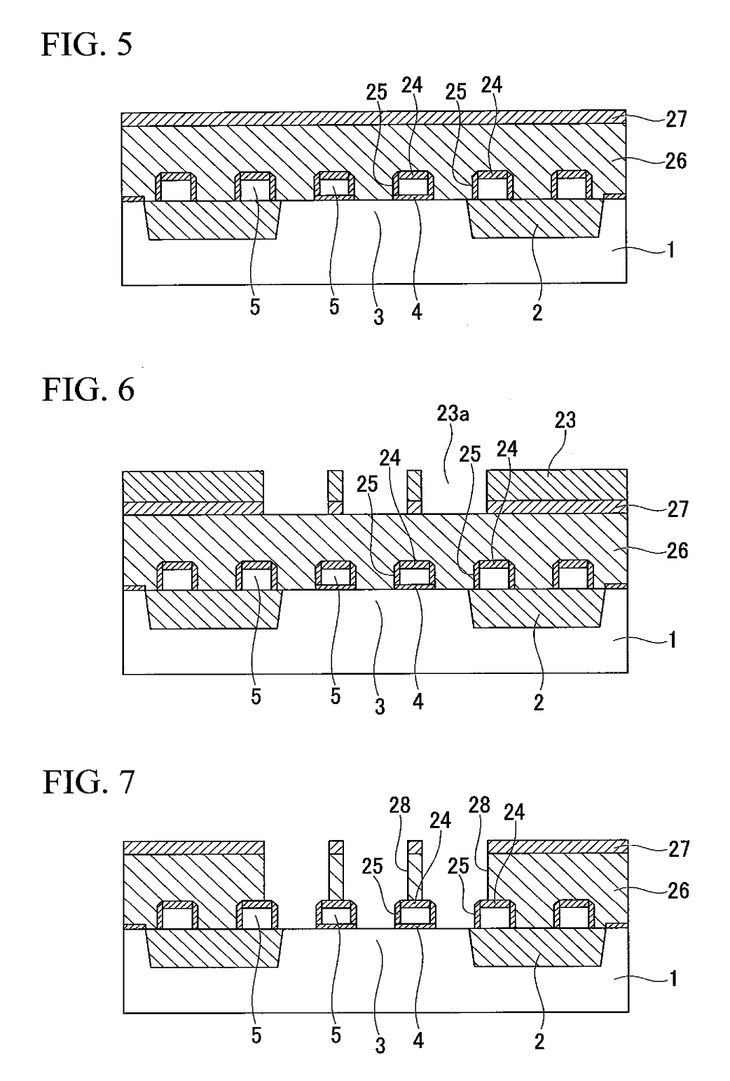

As shown in FIG. 5, a dummy inter-layer insulator 26 is formed over the semiconductor substrate 1, so that the dummy inter-layer insulator 26 covers the silicon oxide films 24 and the side wall insulators 25. The dummy inter-layer insulator 26 has a thickness of 300 nanometers. The dummy inter-layer insulator 26 is made of amorphous carbon. The amorphous carbon film can be formed by a plasma enhanced CVD. The plasma enhanced CVD can be carried out at a temperature of 550° C. by using butane (C₄H₁₀) as a source gas. The source gas may be other hydrocarbon gas than butane. The temperature at which the amorphous carbon film is formed may be ranged from 20° C. to 700° C. The method of forming the amorphous carbon film should not be limited to the plasma enhanced CVD but may be other methods. At this step, the word lines 25 which are covered by the silicon oxide films 24 and the side wall insulators 25 are covered by the dummy inter-layer insulator 26. A silicon oxide film 27 having a thickness of 70 nanometers is formed over the dummy inter-layer insulator 26 by plasma enhanced CVD.

As shown in FIG. 6, a photo-resist pattern 23 is formed over the silicon oxide film 27 by a known lithography process. The photo-resist pattern 23 has openings 23a. The openings 23a are positioned at first contact hole formation regions. The width of the openings 23a of the photo-resist pattern 23 is wider than the distance between adjacent two of the word lines 5 so that the openings 23a partially overlap the word lines 5, even this is not essential to the present invention.

The photo-resist pattern 23 is used as a mask to perform a selective dry etching process for selectively etching the silicon oxide film 27. The dry etching process is carried out by using a fluorine-containing reaction gas in plasma state. The silicon oxide film 27 as etched has the same pattern as the photo-resist pattern 23.

When the photo-resist film is patterned by irradiation of a light, it is necessary to provide an anti-reflecting coat having a thickness of 100 nanometers under the photo-resist film so that the anti-reflecting coat prevents that the irradiated light is reflected or diffracted by the base layer underlying the photo-resist film. The dummy inter-layer insulator 26 of amorphous carbon shows optical absorption. The dummy inter-layer insulator 26 of amorphous carbon can perform as an anti-reflecting film. Thus, the dummy inter-layer insulator 26 of amorphous carbon makes it unnecessary to provide an anti-reflecting coat, even the anti-reflecting coat may be provided in addition to the dummy inter-layer insulator 26 of amorphous carbon. In some cases, an oxynitride silicon film having a thickness of 15 nanometers can be formed by plasma enhanced CVD.

As shown in FIG. 7, the silicon oxide film 27 is used as a mask to perform a dry etching process for selectively etching the dummy inter-layer insulator 26 of amorphous carbon, thereby forming first contact holes 28 which penetrate the stack of the silicon oxide film 27 and the dummy inter-layer insulator 26. The amorphous carbon is formed of carbon. The dry etching process is carried out using plasma of a mixture gas of oxygen and argon. The reaction gas used for the dry etching process is free of halogen such as fluorine or chlorine. Using the halogen-free reaction gas causes almost no etching of the silicon oxide films 27 and 24 and the side wall insulators 25 of silicon oxide. Using the halogen-free reaction gas can etch the dummy inter-layer insulator 26 of amorphous carbon only, while the silicon oxide films 27 and 24 and the side wall insulators 25 of silicon oxide are not substantially etched. When the halogen-free reaction gas is used, the etching rate ratio of the dummy inter-layer insulator 26 of amorphous carbon to the silicon oxide films 27 and 24 and the side wall insulators 25 of silicon oxide is almost infinite.

The dummy inter-layer insulator 26 of amorphous carbon under the openings 23a of the photo-resist pattern 23 is dry-etched by using the halogen-free reaction gas and using the silicon oxide film 27 as a mask. The etching rate of the dummy inter-layer insulator 26 of amorphous carbon is almost constant before the silicon oxide films 24 and the side wall insulators 25 of silicon oxide are exposed. After the silicon oxide films 24 and the side wall insulators 25 of silicon oxide are exposed, the dummy inter-layer insulator 26 of amorphous carbon is maintained to be etched at the constant etching rate, while the silicon oxide films 24 and the side wall insulators 25 of silicon oxide are almost not etched, resulting in that parts of the surface of the semiconductor substrate 1 are exposed.

When the etching regions, for example, the openings 23a of the photo-resist pattern 23 partially overlap the word lines 5, the first contact holes 28 are self-aligned to the silicon oxide films 24 and the side wall insulators 25 of silicon oxide, while the word lines 5 remain covered by the silicon oxide films 24 and the side wall insulators 25 of silicon oxide. This etching process relaxes the necessary accuracy in processing the photo-resist pattern.

As described above, the etching rate ratio of the dummy inter-layer insulator 26 of amorphous carbon to the silicon oxide films 24 and the side wall insulators 25 of silicon oxide is almost infinite. Even if the etching rate of the dummy inter-layer insulator 26 of amorphous carbon is reduced by the shrinkage of the first contact holes 28, the etching rate ratio of the dummy inter-layer insulator 26 of amorphous carbon to the silicon oxide films 24 and the side wall insulators 25 of silicon oxide is extremely large. The above-described dry etching process can form the contact holes such as the first contact holes 28 which have a small diameter, while preventing the word lines 5 from being exposed. This can realize further shrinkage of a semiconductor device.

The dummy inter-layer insulator 26 of amorphous carbon is etched by a dry etching process using plasma of mixture gas of oxygen and argon. The condition for plasma may be a pressure of 15 mTorr (2.0 Pa), a high frequency power of 300 W, and a temperature of 20° C. Typical examples of the reaction gas that can be used for the dry etching process may include, but is not limited to, the above-described mixture gas of oxygen and argon, a mixture gas of hydrogen and nitrogen, and an ammonium gas.

In accordance with this embodiment, the insulating films 24 on the top surface of the word line 5 and the side wall insulators 25 on the side walls of the word line 5 are made of silicon oxide. The silicon oxide film is lower in dielectric constant than the silicon nitride film that has conventionally been used for self-alignment technique. As compared to using the silicon nitride film, using the silicon oxide film for covering the word line 5 reduces parasitic capacitance between the first contact plugs 7, 8 and the word line 5. The insulating films which cover the top surface of the side walls of the word line should not be limited to the silicon oxide film. Other insulating films such as the silicon nitride film may be used for covering the upper surface and side walls of the word line 5, provided that the etching rate ratio of the amorphous carbon to the other insulating films is extremely large, for example, at least 100. When the insulating film is used for covering the top and side walls of the word line 5 provided that the etching rate ratio of the amorphous carbon film to the other insulating film is at least 100, this allows that the first contact hole 28 is formed while preventing the word line 5 from being exposed.

The dummy inter-layer insulator 26 of amorphous carbon is etched by the dry etching process, while the photo-resist pattern 23 is entirely etched and the silicon oxide film 27 resides.

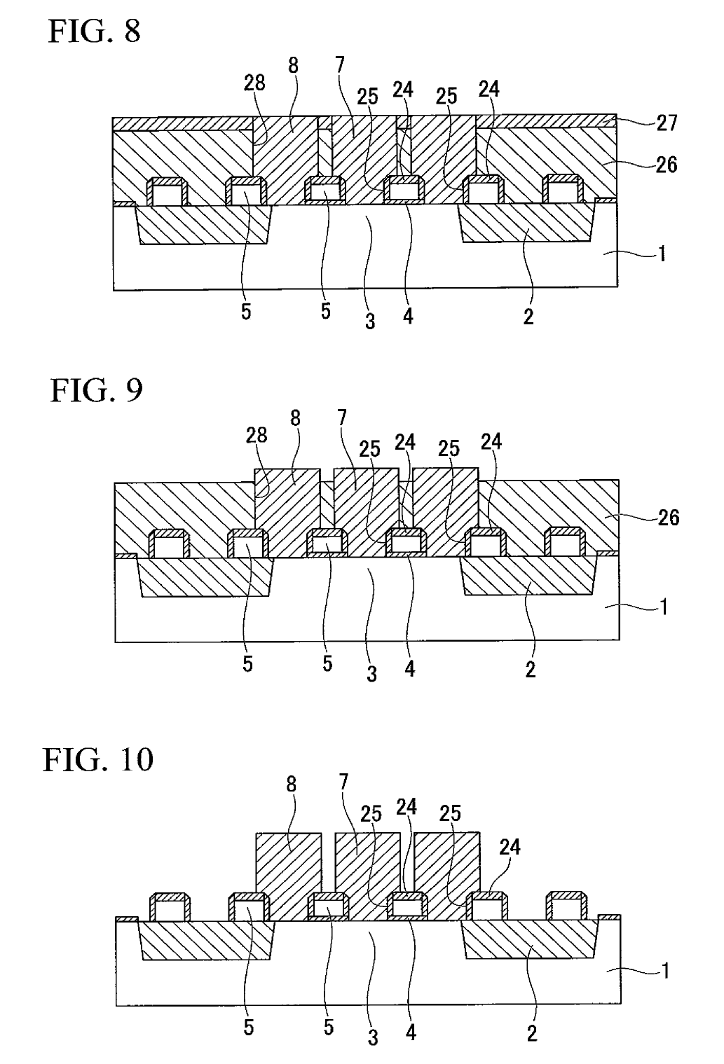

As shown in FIG. 8, a phosphorus-doped polysilicon film is formed by a CVD method in the first contact holes 28 and over the silicon oxide film 27, so that the phosphorus-doped polysilicon film fills up the first contact holes 28. The phosphorus-doped polysilicon film is etched back so as to leave the phosphorus-doped polysilicon film only within the first contact holes 28, thereby forming first and contact plugs 7, 8 of phosphorus-doped polysilicon.

For forming the first and contact plugs 7, 8, it is possible to deposit the polycrystalline silicon film. It is also possible to deposit an amorphous silicon film, followed by further conducting a heat treatment to the amorphous silicon film, thereby forming the polycrystalline silicon film.

The amorphous carbon film can be formed by a relatively low temperature, for example, 550° C. It is preferable to form the polycrystalline silicon film as at a lower temperature as possible in light of avoiding thermal deformation of the amorphous carbon film. The lowest temperature necessary for forming the silicon film in polycrystal state is 600° C. The lowest temperature necessary for forming the silicon film in amorphous state is 530° C. It is possible to avoid any substantive thermal deformation of the amorphous carbon film. It is more preferable to form an amorphous silicon film, followed by conducting a heat treatment to poly-crystallize the amorphous silicon film, thereby obtaining a polycrystalline silicon film.

As shown in FIG. 9, the silicon oxide film 27 is removed by a buffered hydrofluoric (BHF) acid. Using the buffered hydrofluoric (BHF) acid removes the silicon oxide film 27 only, while the first contact plugs 7, 8 and the dummy inter-layer insulator 26 of amorphous carbon are not etched.

As shown in FIG. 10, the dummy inter-layer insulator 26 of amorphous carbon is entirely removed. Removing the dummy inter-layer insulator 26 of amorphous carbon can be made by a dry etching process using a halogen-free gas in plasma state such as oxygen gas in plasma, without using any reaction gas that contains halogen such as fluorine. The same reaction gas as that used for forming the first contact hole 28 can also be used for removing the dummy inter-layer insulator 26 of amorphous carbon. Using the halogen-free gas in plasma state can remove the dummy inter-layer insulator 26 of amorphous carbon without providing any substantive influence to the first contact plugs 7, 8, the silicon oxide film 24, and the side wall insulators 25. Removing the dummy inter-layer insulator 26 of amorphous carbon causes that pillars of the first contact plugs 7, 8 are formed.

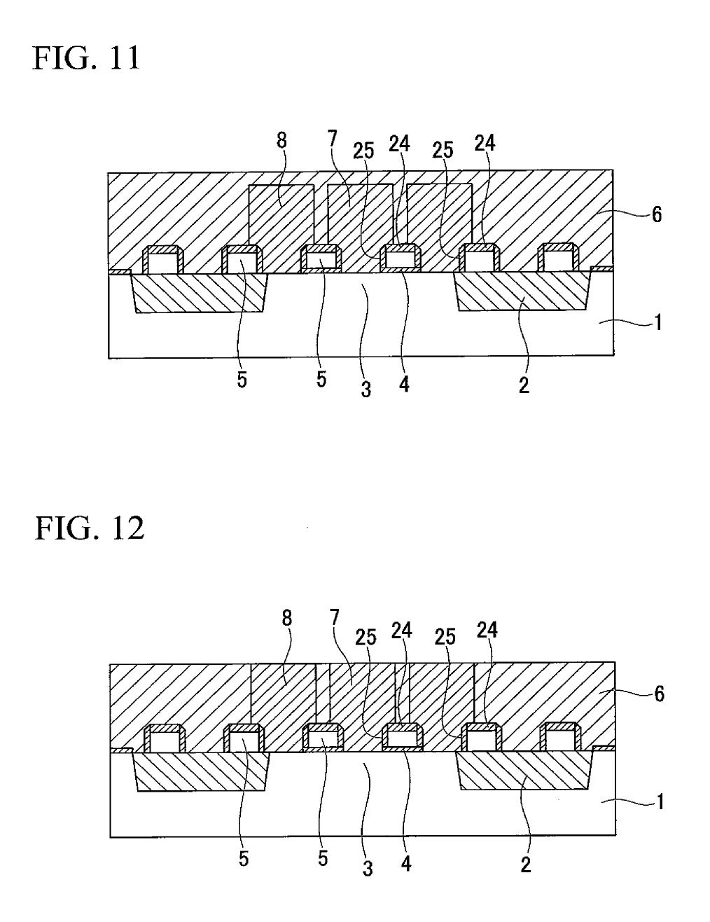

As shown in FIG. 11, a first inter-layer insulator 6 of silicon oxide having a thickness of 350 nanometers is formed over the semiconductor substrate 1 so that the first inter-layer insulator 6 covers the first contact plugs 7, 8. The first inter-layer insulator 6 can be formed by a bias HDP(high density plasma)-CVD method using monosilane (SiH₄) and oxygen as source gases.

As shown in FIG. 12, the first inter-layer insulator 6 of silicon oxide is polished by a CMP (Chemical Mechanical Polishing) so that the top surfaces of the contact plugs 7, 8 are exposed.

With reference again to FIG. 1, a second inter-layer insulator 9 of silicon oxide having a thickness of 400 nanometers is formed over the first inter-layer insulator 6, and the first contact plugs 7, 8 by the same method as that used for forming the first inter-layer insulator 6.

A photo-resist pattern is formed over the second inter-layer insulator 9. The photo-resist pattern is used as a mask to carry out a dry etching process for selectively etching the second inter-layer insulator 9, thereby forming a second contact hole 29. The second contact hole 29 penetrates the second inter-layer insulator 9 and reaches the first contact plug 7. The photo-resist pattern is removed by the dry etching process.

A titanium film having a thickness of about 10 nanometers is formed in the second contact hole 29 and over the second inter-layer insulator 9. A titanium nitride film having a thickness of about 20 nanometers is formed on the titanium film within the second contact hole 29 and over the second inter-layer insulator 9. A tungsten film is formed on the titanium nitride film so that the tungsten film fills up the second contact hole 29 and extends over the second inter-layer insulator 9, thereby forming a stack of the titanium film, the titanium nitride film, and the tungsten film. The stack of the titanium film, the titanium nitride film, and the tungsten film is partially removed by the CMP method, so as to leave the stack within the second contact hole 29 only, thereby forming a second contact plug 10.

A titanium nitride film having a thickness of about 10 nanometers is formed by a sputtering process over the second inter-layer insulator 9 and the second contact plug 10. A tungsten film having a thickness of about 50 nanometers is formed by a sputtering process over the titanium nitride film, thereby forming a stack of the titanium nitride film and the tungsten film. A photo-resist pattern is formed over the tungsten film. The photo-resist pattern is used as a mask to carry out a dry etching process for selectively etching the stack of the titanium nitride film and the tungsten film, thereby forming bit lines 11 as second interconnection layers. A silicon nitride passivation film having a thickness of about 10 nanometers is formed which covers the surfaces of the bit lines 11 by a CVD method. The silicon nitride passivation film performs as a passivation film which protects the bit lines 11. The silicon nitride passivation film is not illustrated.

A third inter-layer insulator 12 is formed of silicon oxide having a thickness of 200 nanometers is formed over the second inter-layer insulator 9 and the bit lines 11 by the same method as that used for forming the first inter-layer insulator 6.

A photo-resist pattern is formed over the third inter-layer insulator 12. The photo-resist pattern is used as a mask to carry out a dry etching process for selectively etching the third inter-layer insulator 12, the bit lines 11 and the second inter-layer insulator 9, thereby forming third contact holes 30. The third contact holes 30 penetrate the third inter-layer insulator 12, the bit lines 11 and the second inter-layer insulator 9, so that the third contact holes 30 reach the first contact plugs 8. The photo-resist pattern is removed by a dry etching process.

A phosphorus-doped polycrystalline silicon film is formed within the third contact holes 30 and over the third inter-layer insulator 12 by a CVD method, so that the phosphorus-doped polycrystalline silicon film fills up the third contact holes 30. The phosphorus-doped polycrystalline silicon film is etched back to leave the phosphorus-doped polycrystalline silicon film within the third contact holes 30 only, thereby forming third contact plugs 13 of phosphorus-doped polycrystalline silicon in the third contact holes 30.

An etching stopper nitride film that is not illustrated is formed over the third inter-layer insulator 13 and the third contact plugs 13. A fourth inter-layer insulator 14 of silicon oxide having a thickness of 2000 nanometers is formed on the etching stopper nitride film by the same method as that used for forming the third inter-layer insulator 6. A photo-resist pattern is formed on the fourth inter-layer insulator 14. The photo-resist pattern is used to carry out a dry etching process for selectively etching the fourth inter-layer insulator 14, thereby forming a cylinder hole 31. The cylinder hole 31 penetrates the fourth inter-layer insulator 14 and reaches the third contact plugs 13.

A wet etching process is carried out using a fluorine-containing solution to remove a spontaneous oxide film from the surfaces of the third contact plugs 13, in order to suppress resistance between the third contact plugs 13 and a bottom electrode 15 that will be formed later.

A titanium film is formed on the side walls and bottom of the cylinder hole 31 by a high temperature plasma enhanced CVD. A titanium nitride film is formed on the titanium film by a hot CVD, thereby forming a stack of the titanium film and the titanium nitride film on the side walls and bottom of the cylinder hole 31. The stack of the titanium film and the titanium nitride film performs as a bottom electrode 15. The titanium film has a thickness of about 10 nanometers. The titanium nitride film has a thickness of about 20 nanometers. The titanium film is formed at a temperature of about 650° C. thereby causing a silicide reaction in-situ between titanium of the titanium film and silicon of the third contact plug 13. The silicidation reaction is caused at the bottom of the cylinder hole 31. As a result of the silicide reaction in-situ of Ti and Si at the bottom of the cylinder hole 31, a titanium silicide (TiSi₂) being lowly resistive is formed on the interface between the contact plug 13 and the bottom electrode 15.

The stack of the titanium film and the titanium nitride film is partially removed from the upper surface of the fourth inter-layer insulator 14, thereby defining the bottom electrode 15 within the cylinder hole 31.

A capacitive insulating film 16 of a high dielectric material having a thickness in the order of a few nanometers is formed on the bottom electrode 15 within the cylinder hole 31 and on the upper surface of the fourth inter-layer insulator 14. A top electrode 17 of titanium nitride is formed on the capacitive insulating film 16.

A fifth inter-layer insulator 18 of silicon oxide having a thickness of 800 nanometers is formed on the top electrode 17 by the same method as that used for forming the first inter-layer insulator.

A conductive film is formed on the fifth inter-layer insulator 18. A photo-resist pattern is formed on the conductive film. The photo-resist pattern is used as a mask to carry out a dry etching process for selectively etching the conductive film, thereby forming third interconnection layers 19.

As a result, the semiconductor device has been completed.

In accordance with the above-described embodiment, the dummy inter-layer insulator 26 of amorphous carbon is formed, while the upper and side walls of the word lines 5 are covered by the insulating films such as the silicon oxide film or the silicon nitride film. Amorphous carbon can be dry-etched by the plasma of a halogen-free reaction gas which may contain oxygen, hydrogen, or ammonium. Using the halogen-free reaction gas can etch the dummy inter-layer insulator 26 of amorphous carbon only thereby forming first contact holes 28 in the dummy inter-layer insulator 26 of amorphous carbon, while the silicon oxide films 27 and 24 and the side wall insulators 25 of silicon oxide are not substantially etched. Even after the first contact holes 26 are formed in the dummy inter-layer insulator 26 of amorphous carbon, the silicon oxide films 24 and the side wall insulators 25 of silicon oxide reside on the upper surface and side walls of each word line 5. The silicon oxide films 24 and the side wall insulators 25 of silicon oxide prevent short circuit between the word line 5 and the first contact plugs 7, 8.

After the first contact plugs 7, 8 have been formed, the dummy inter-layer insulator 26 of amorphous carbon can selectively be removed without providing any influence to the other elements or structure that have already been presented at this time. This can allow that the first inter-layer insulator 6 is formed which covers the first contact plugs 7, 8, thereby allowing the further processes in the same manners as those used in the prior art.

### Second Embodiment

A second embodiment of the present invention will be described. The second embodiment provides a method to avoid a short circuit between the first contact plugs 7, 8 through voids. In accordance with the above-described first embodiment, the first contact holes 28 are formed in the dummy inter-layer insulator 26 of amorphous carbon. Then, the first contact plugs 7, 8 of phosphorus-doped polycrystalline silicon are formed in the first contact holes 28. The dummy inter-layer insulator 26 of amorphous carbon is somewhat poor in step-coverage due to it having been formed by the plasma enhanced CVD. When the word lines 5 are aligned at high density, and the pitch between adjacent two of the word lines 5 is narrow, then the dummy inter-layer insulator 26 of amorphous carbon can not completely fill up the gap between the adjacent two of the word lines 5, thereby forming any void in the dummy inter-layer insulator 26 of amorphous carbon between the adjacent two of the word lines 5. Once voids are formed in the dummy inter-layer insulator 26 of amorphous carbon between the adjacent two of the word lines 5, the contact plugs 7, 8 are formed while silicon enters into the voids. The silicon films on the voids may form a short circuit between the adjacent two of the contact plugs 7,8 through the silicon film or films in the void or voids.

The method of forming the semiconductor device in accordance with the second embodiment is to prevent the short circuit formation between the contact plugs 7, 8 due to the void formation.

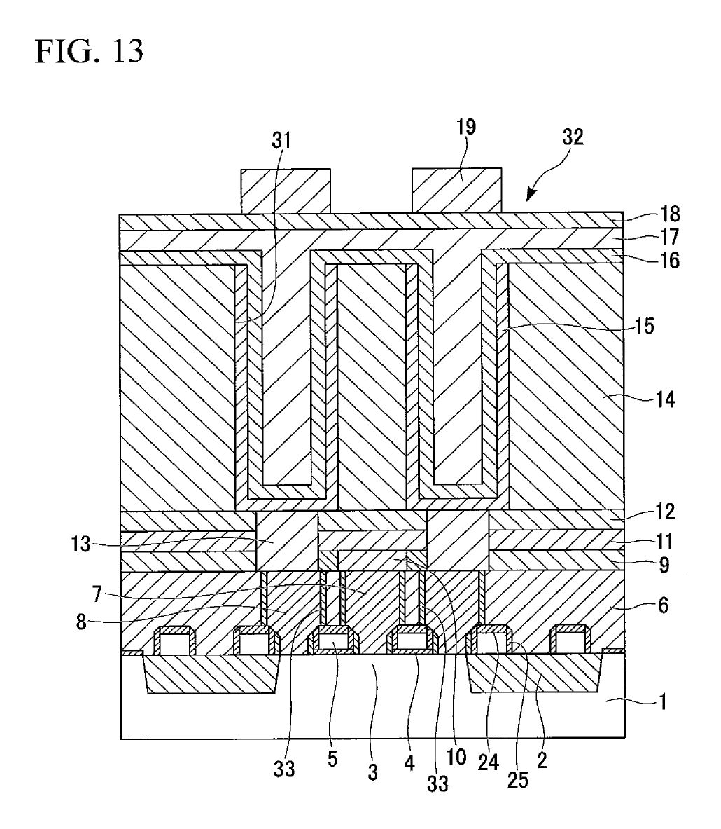

An example of a semiconductor device that is formed by a method of forming it will be described. FIG. 13 is a fragmentary cross sectional elevation view illustrating a memory cell structure of a semiconductor device, taken along a line that runs parallel to a bit line and perpendicular to a word line, which is formed by a method of forming it accordance with a second preferred embodiment of the present invention. The semiconductor deice of this second embodiment has the same structure as that of the first embodiment. The following descriptions will focus on the differences of the second embodiment from the first embodiment.

The differences of the second embodiment from the first embodiment is that additional insulating films, for example, silicon nitride films 33 are formed on the side walls of the contact holes 28 in the first inter-layer insulator 6.

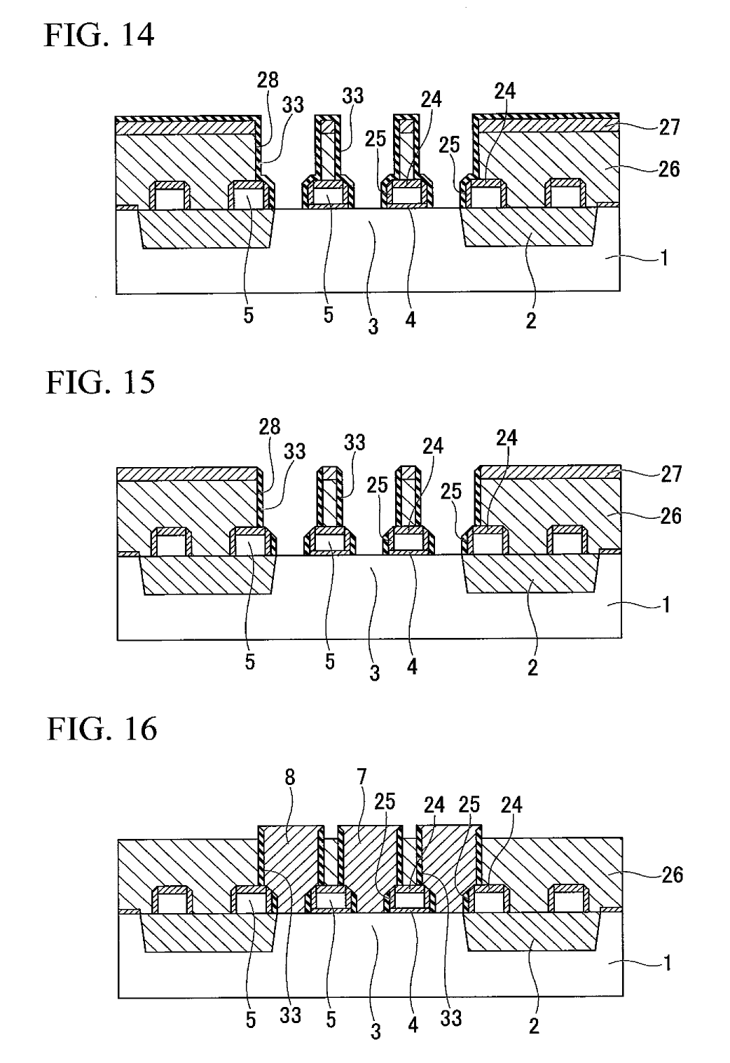

A method of forming a semiconductor device will be described. FIGS. 14 through 19 are fragmentary cross sectional elevation views illustrating semiconductor devices in sequential steps involved in a method of forming the same in accordance with the second embodiment of the present invention.

Similarly to the first embodiment, the device isolation regions 2, the n-diffusion layers 3, the gate insulating films 4, the word line 5, the dummy inter-layer insulator 26 of amorphous carbon, the silicon oxide film 27 and the first contact holes 28 are formed over the semiconductor substrate 1.

As shown in FIG. 14, a silicon nitride film 33 as an insulator is formed on the side walls of the bottom of the first contact holes 28 in the dummy inter-layer insulator 26 of amorphous carbon as well as on the silicon oxide film 27. The silicon nitride film 33 has a thickness of 10 nanometers.

Voids may be present in the dummy inter-layer insulator 26 of amorphous carbon between the adjacent two of the word lines 5. Some of the voids that are adjacent to the first contact holes 28 in the dummy inter-layer insulator 26 of amorphous carbon can be plugged with the silicon nitride film 33.

The silicon nitride film 33 can be formed by a plasma enhanced CVD using silane (SiH₄) and ammonium (NH₃). The temperature for forming the silicon nitride film 33 may, for example, be 450° C., but may be in the range of 250° C. to 500° C.

The method of forming the silicon nitride film 33 should not be limited to the plasma enhanced CVD, but may be other available methods such as an ALD (Atomic Layer Deposition) method.

The silicon nitride film 33 can be replaced by other insulating films such as a silicon oxide film that is formed by the plasma enhanced CVD.

The thickness of the silicon nitride film 33 may preferably be in the range of 5 nanometers to 3-30 nanometers. When the thickness of the silicon nitride film 33 is thinner than 5 nanometers, it is possible that the silicon nitride film 33 does not completely fill up the voids. When the thickness of the silicon nitride film 33 is thicker than 30 nanometers, it is possible that the silicon nitride film 33 reduces the diameter of the first contact holes 28, thereby making it difficult that the polycrystalline silicon film fills up the first contact holes 28.

As shown in FIG. 15, the silicon nitride film 33 is partially removed by a dry etching process from the bottoms of the first contact holes 28 and from the upper surface of the silicon oxide film 27. As a result, the n-diffusion layer 3 is exposed at the bottoms of the first contact holes 28. The silicon nitride film 33 resides on the side walls of the first contact holes 28 and on the side wall insulators 25. The silicon nitride film 33 plugs some of the voids in the dummy inter-layer insulator 26 of amorphous carbon, wherein the plugged voids are adjacent to the side walls of the first contact holes 28.

As shown in FIG. 16, first contact plugs 7, 8 of phosphorus-doped polycrystalline silicon are formed in the first contact holes 28. The silicon nitride film 33 prevents phosphorus-doped polycrystalline silicon of the first contact plugs 7, 8 from entering into the voids in the dummy inter-layer insulator 26 of amorphous carbon.

The silicon oxide film 27 is removed from the upper surface of the dummy inter-layer insulator 26 of amorphous carbon by a buffered hydrofluoric (BHF) acid.

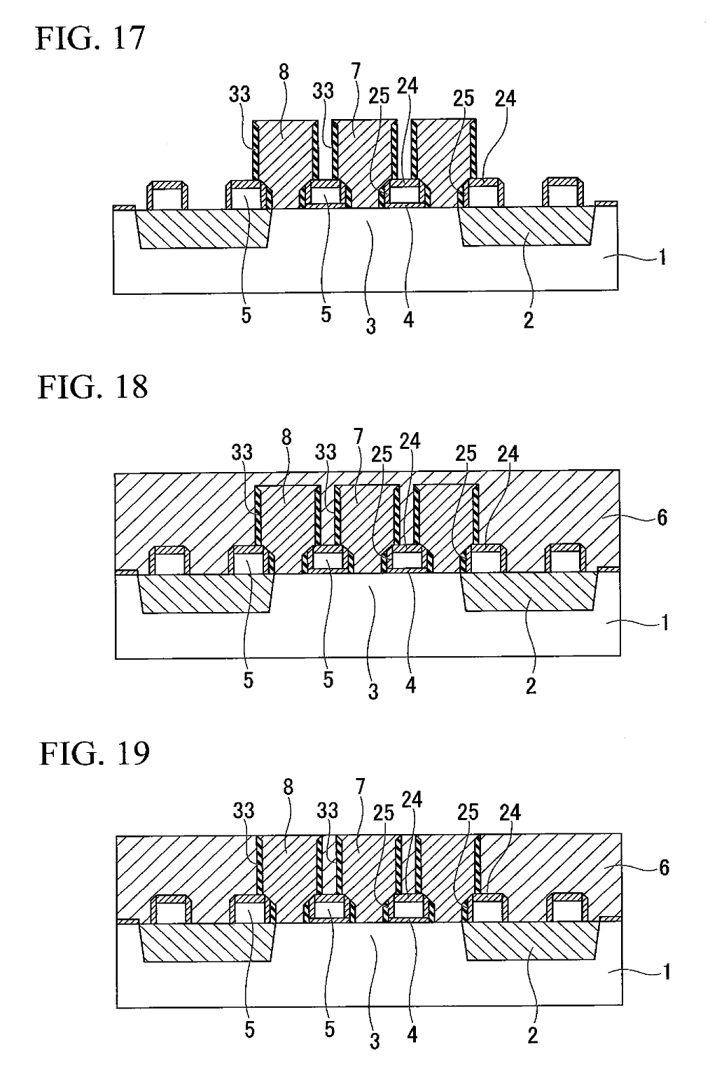

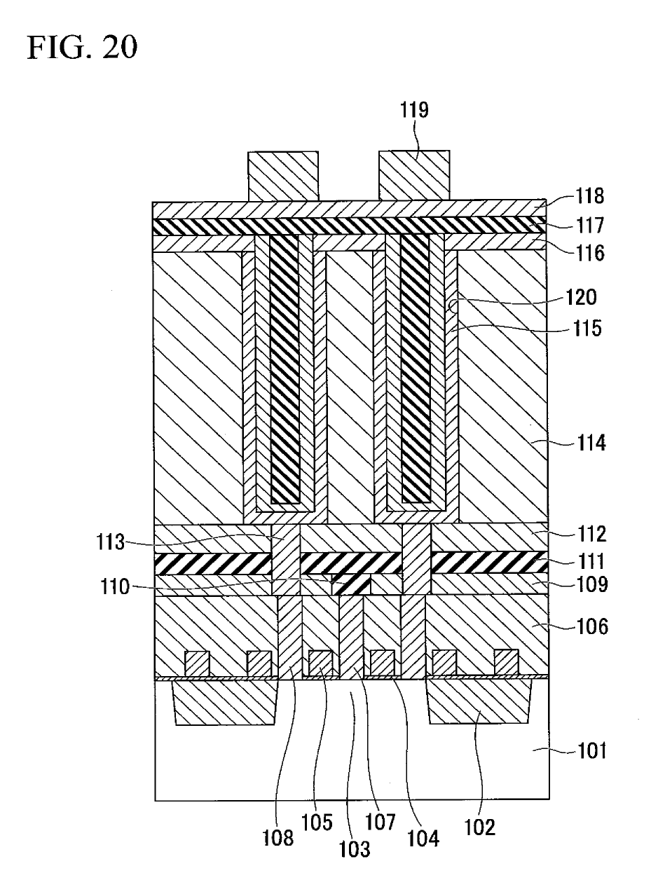

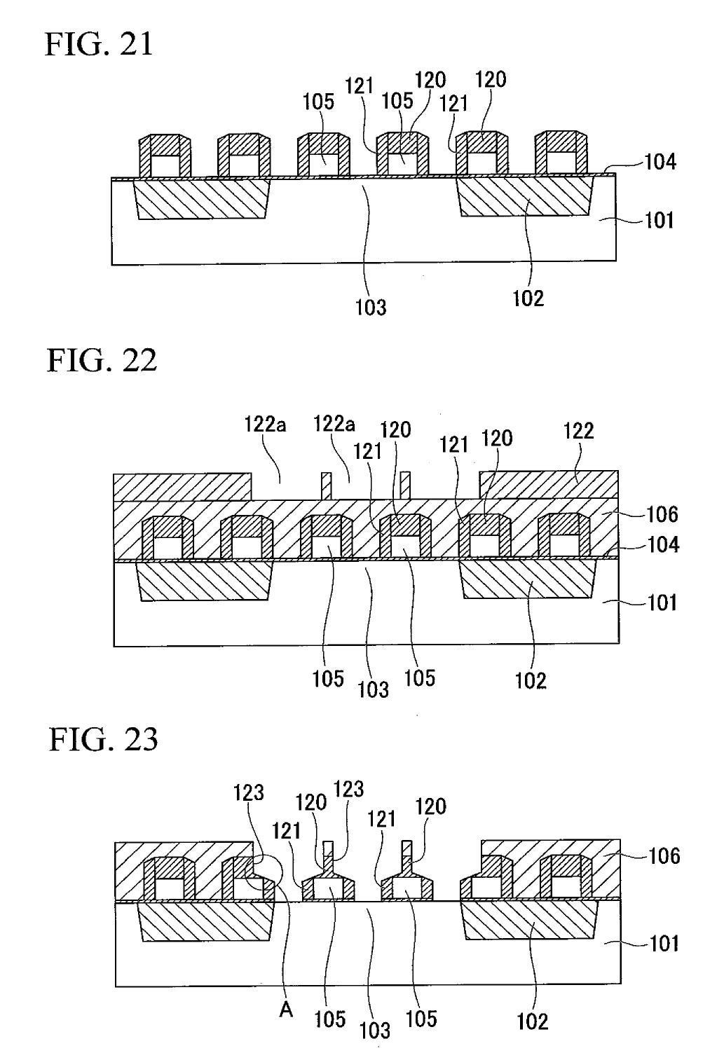

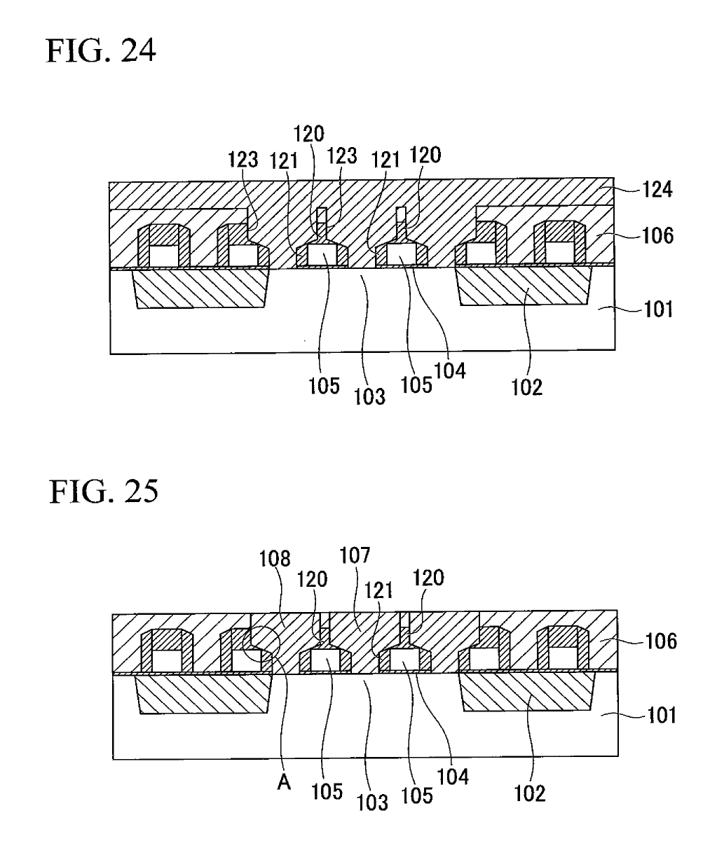

As shown in FIG. 17, the dummy inter-layer insulator 26 of amorphous carbon is removed, thereby forming pillars of the first contact plugs 7, 8, while the silicon nitride film 33 resides on the side walls of the first contact plugs 7, 8.

As shown in FIG. 18, a first inter-layer insulator 6 of silicon oxide is formed over the semiconductor substrate 1 so that the first inter-layer insulator 6 covers the first contact plugs 7, 8. The first inter-layer insulator 6 can be formed by a bias HDP(high density plasma)-CVD method using monosilane (SiH₄) and oxygen as source gases.

As shown in FIG. 19, the first inter-layer insulator 6 of silicon oxide is polished by a CMP (Chemical Mechanical Polishing) so that the top surfaces of the contact plugs 7, 8 are exposed.

The formation of the first contact plugs 7, 8 of phosphorus-doped polycrystalline silicon can be made in the same conditions as those used in the first embodiment. Removals of the silicon oxide film 27 and the dummy inter-layer insulator 26 of amorphous carbon can be made in the same conditions as those used in the first embodiment. The formation of the first inter-layer insulator 6 can be made in the same conditions as those used in the first embodiment. Polishing the first inter-layer insulator 6 can be made in the same conditions as those used in the first embodiment.

The semiconductor device shown in FIG. 13 can be obtained by the same processes as those in the first embodiment.

The second embodiment of the present invention provides the similar effects and advantages as those of the first embodiment.

The second embodiment of the present invention provides additional effects and advantages as follows. In accordance with the second embodiment, the first contact holes 28 are formed in the dummy inter-layer insulator 26 of amorphous carbon and then the silicon nitride film 33 are formed which coats the side walls of the first contact holes 28. The silicon nitride film 33 plugs voids in the dummy inter-layer insulator 26 of amorphous carbon. The silicon nitride film 33 prevents the phosphorus-doped polycrystalline silicon of the first contact plugs 7, 8 from entering into the voids in the dummy inter-layer insulator 26 of amorphous carbon. The silicon nitride film 33 prevents short circuit between the adjacent two of the first contact plugs 7, 8.

The present invention can be applicable to any methods of forming DRAM and hybrid LSI.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A method of forming a contact plug, the method comprising:
forming a dummy film over a substrate, the dummy film including amorphous carbon as a main material;
forming at least one contact hole in the dummy film; and
forming at least one contact plug in the at least one contact hole.

2. The method according to claim 1, further comprising:
forming interconnection layers over the substrate; and
forming a first insulating film over the substrate, the first insulating film covering the interconnection layers, and
wherein forming the dummy film over the substrate comprises forming the dummy film which covers the first insulating film, and
wherein forming the at least one contact hole in the dummy film comprises carrying out an etching process under condition that an etching rate of the dummy film is higher than an etching rate of the first insulating film so that the at least one contact hole penetrates the dummy film and the surface of the substrate is exposed.

3. The method according to claim 2, further comprising:
removing the dummy film by a dry etching process using a reaction gas that is substantially free of halogen, after the at least one contact plug is formed.

4. The method according to claim 2, wherein forming the etching process comprises a dry etching process using a reaction gas that is substantially free of halogen.

5. The method according to claim 4, wherein the reaction gas contains at least one of oxygen, hydrogen, and ammonium.

6. The method according to claim 2, wherein a ratio in etching rate of the dummy film to the first insulating film is at least 100.

7. The method according to claim 2, further comprising:
forming a second insulating film on side walls of the at least one contact hole, and
wherein the at least one contact plug is formed adjacent to the second insulating film.

8. The method according to claim 7, wherein the etching process is carried out under condition that the etching rate of the dummy film is higher than an etching rate of the second insulating film.

9. A method of forming a semiconductor device, the method comprising:
forming a dummy film over a substrate having interconnection layers, the dummy film covering the interconnection layers, the dummy film including amorphous carbon as a main material;
forming at least one contact hole in the dummy film; and
forming at least one contact plug in the at least one contact hole.

10. The method according to claim 9, further comprising:
forming a first insulating film over the substrate, the first insulating film covering the interconnection layers, and
wherein forming the dummy film over the substrate comprises forming the dummy film which covers the first insulating film, and
wherein forming the at least one contact hole in the dummy film comprises carrying out an etching process under condition that an etching rate of the dummy film is higher than an etching rate of the first insulating film so that the at least one contact hole penetrates the dummy film and the surface of the substrate is exposed.

11. The method according to claim 9, further comprising:
removing the dummy film by a dry etching process using a reaction gas that is substantially free of halogen, after the at least one contact plug is formed; and
forming an inter-layer insulator over the substrate, the inter-layer insulator covering the at least one contact plug and the first insulating film.

12. The method according to claim 9, wherein the interconnection layers have stripe patterns;
forming the at least one contact hole comprises forming the at least one contact hole between the interconnection layers.

13. The method according to claim 10, wherein the first insulating film includes mainly at least any one of silicon oxide and silicon nitride.

14. The method according to claim 10, wherein the first insulating film includes mainly silicon oxide.

15. The method according to claim 9, wherein forming the at least one contact hole comprises carrying out a dry etching process using a reaction gas that is substantially free of halogen.

16. The method according to claim 15, wherein the reaction gas contains at least one of oxygen, hydrogen, and ammonium.

17. The method according to claim 10, wherein a ratio in etching rate of the dummy film to the first insulating film is at least 100.

18. The method according to claim 10, further comprising:
forming a second insulating film on side walls of the at least one contact hole, and
wherein the at least one contact plug is formed adjacent to the second insulating film.

19. The method according to claim 18, wherein the etching process is carried out under condition that the etching rate of the dummy film is higher than an etching rate of the second insulating film.
